(19) United States
(12) Patent Application Publication
(10) Pub. No.: US 2009/0283848 A1
(43) Pub. Date: Nov. 19, 2009

(54) Photodiode Assembly With Improved Electrostatic Discharge Damage Threshold

(75) Inventors: I-Hsing Tan, Cupertino, CA (US); Shuping Shang, Shenzhen (CN); Oleg Bouevitch, Ottawa (CA)

Correspondence Address: Pequignot + Myers LLC, 140 Marine View Avenue, Suite 220, Solana Beach, CA, 92075, US

(73) Assignee: JDS Uniphase Corporation, Milpitas, CA (US)

(21) Appl. No.: 12/119,667

(22) Filed: May 13, 2008

(51) Int. Cl. H01L 29/866

(52) U.S. Cl. 257/438; 257/E29.335

(57) ABSTRACT

A photodiode with an improved electrostatic damage threshold is disclosed. A Zener or an avalanche diode is connected in parallel to a photodiode. Both diodes are integrated into the same photodiode housing. The diodes can be mounted on a common header or onto each other. An avalanche photodiode and an avalanche diode can be fabricated on a common semiconductor substrate. A regular p-n diode connected in series, cathode-to-cathode or anode-to-anode, to a Zener diode, forms a protection circuit which, when connected in parallel to a photodiode, provides a smaller electrical capacity increase as compared to a simpler circuit consisting just of a Zener or an avalanche diode.

### TECHNICAL FIELD

The present invention is related to photodiodes, and specifically to photodiodes having high electrostatic damage threshold.

### BACKGROUND OF THE INVENTION

Photodiodes are semiconductor photodetectors capable of converting light into electric current or voltage. The most commonly used photodetectors are positive-negative (p-n) photodiodes, positive-intrinsic-negative (p-i-n) photodiodes, and avalanche photodiodes.

A photon absorbed at a p-n junction of a p-n photodiode, or at an intrinsic region, or i-region, of a p-i-n photodiode, generates a pair of current carriers, a hole in the valence band and the electron in the conduction band, which drift towards respective p- and n-doped areas. When reverse biased with an external voltage source, a photodiode converts light into a current. When left unbiased, a photodiode generates a small voltage, of the order of one Volt, in response to light. An avalanche photodiode is, in its simplest form, a p-i-n diode with very high reverse bias voltage applied. More advanced avalanche photodiodes include an additional layer called multiplication layer, in which the current carriers multiply through a process called impact ionization.

Due to their simplicity, compactness, and ease of operation, photodiodes have found a widespread use in consumer electronics devices such as compact disc players, smoke detectors, and the receivers for remote controls in DVD players and televisions. Photodiodes are frequently used for accurate measurement of optical power in science and industry, as well as in various medical applications. In optical communication systems, photodiodes are used to convert optical signals into electrical signals.

However, presently many commercially available photodiodes are susceptible to damage due to a discharge of static electricity from a neighboring object such as a human body. The electrostatic discharge, or ESD, can result in a fast electric transient of a few thousand Volts and is one of the common causes of failure of photodiodes and other sensitive electronic devices. In an attempt to protect photodiodes from ESD, the electronics manufacturers control air humidity, provide grounded floors and tabletops, and introduce special packaging procedures and materials. These measures are expensive to implement and are not completely effective, with residual ESD damage being sometimes difficult to detect. Furthermore, an ESD can damage the photodiodes at a customer site, if similar precautionary measures are not implemented.

A general approach to protect an electronic device from an ESD is to connect its terminals in parallel to a voltage-clamping circuit which has a high electrical resistance at an operating voltage of the device to be protected, typically a few Volts to tens of Volts, and a low electrical resistance at high voltages of an ESD pulse, which, as was noted, can reach thousands of Volts. In particular, Zener diodes have been used for ESD protection, due to the ability of Zener diodes to provide the voltage clamping function when reverse biased. Avalanche diodes, which are very similar to Zener diodes, but use a different physical mechanism to provide the voltage-clamping function, can also be employed. For brevity, “Zener diode” means a Zener or an avalanche diode herefrom. Other voltage-clamping components, which may be used for the same purpose, include metal-oxide varistors and transient-voltage-suppressor (TVS) diodes.

With the aforesaid state of the art as a point of departure, the principal object of the present invention is to provide an inexpensive, simple photodiode having an improved ESD damage threshold.

### SUMMARY OF THE INVENTION

In accordance with the invention there is provided a photodiode assembly with improved electrostatic discharge damage threshold, comprising:
a substrate,
a photodiode structure having first and second electrical terminals, and
a protective diode structure having first and second electrical terminals, wherein
the substrate supports the photodiode and the protective diode structures;
the first terminal of the photodiode structure is connected to the first terminal of the protective diode structure; and
the second terminal of the photodiode structure is connected to the second terminal of the protective diode structure.

In accordance with another aspect of the present invention there is further provided a photodiode assembly comprising a photodiode having a cathode and an anode, and an electrostatic discharge protective circuit having first and second electric terminals, wherein the photodiode and the electrostatic discharge protective circuit are connected in parallel, and the electrostatic discharge protective circuit comprises a protective diode having a cathode and an anode.

### BRIEF DESCRIPTION OF THE DRAWINGS

Exemplary embodiments will now be described in conjunction with the drawings in which:

FIG. 1 is an electrical connections diagram of a prior-art ESD-protected light emitting diode;

FIG. 2 is a top view of an ESD-protected photodiode housing of the present invention;

FIG. 3 is a cross-sectional view showing a Zener diode chip and a photodiode chip mounted onto a common conductive substrate by the way of a solder bump and wire bonding;

FIG. 4 is a cross-sectional view showing a Zener diode chip mounted onto a photodiode chip by the way of a solder bump and wire bonding;

FIG. 5 is a cross-sectional view of an avalanche photodiode stack and avalanche diode stack manufactured on a common substrate;

FIGS. 6A, 6B, and 6C are electrical diagrams illustrating preferred connection configurations of a photodiode to a protective diode;

FIGS. 7A and 7B are electrical diagrams illustrating preferred connection configurations of a photodiode to a protective circuit consisting of a Zener diode and a regular p-n diode.

### DETAILED DESCRIPTION OF THE INVENTION

While the present teachings are described in conjunction with various embodiments and examples, it is not intended that the present teachings be limited to such embodiments. On the contrary, the present teachings encompass various alternatives, modifications and equivalents, as will be appreciated by those of skill in the art.

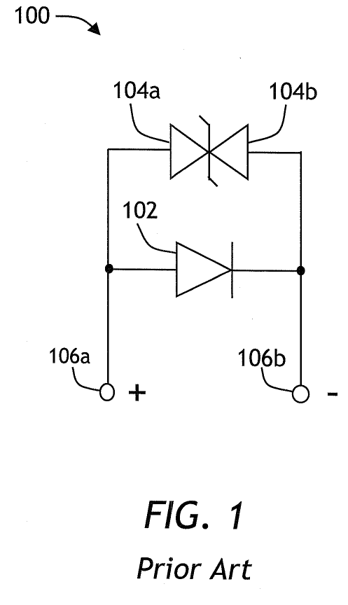

FIG. 1 shows a prior art protection circuit 100 for a light emitting diode, or LED 102, comprising a pair of Zener diodes 104a and 104b connected in parallel to LED 102. In operation, a voltage is applied to electrodes 106a and 106b so as to make LED 102 emit light. Since Zener diodes 104a and 104b are connected cathode-to-cathode, they exhibit high electric resistance and, therefore, in operation, almost all of the electric current flows through LED 102. When an ESD pulse of either polarity arrives, the Zener diodes 104a and 104b conduct, short-circuiting the path of electric current and protecting LED 102.

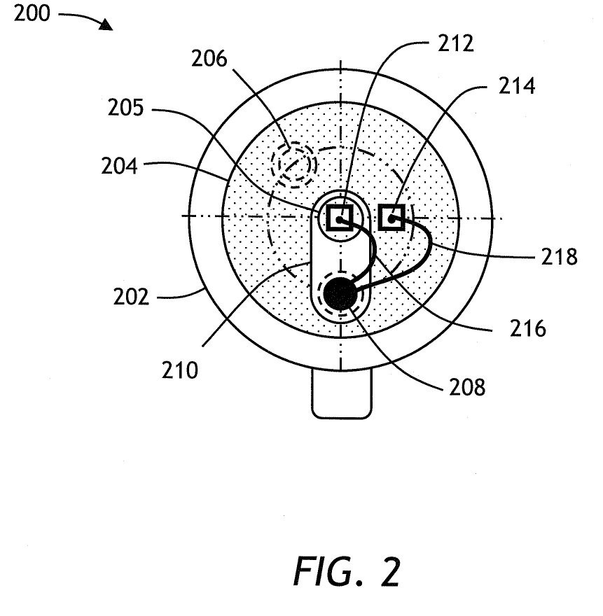

Turning now to FIG. 2, a top view of an ESD-protected photodiode assembly 200 is shown consisting of a housing 202 having an electrically conductive header 204, a ground terminal 206 electrically coupled to header 204, an output terminal 208, and an insulating pad 210. A photodiode chip 212 and a protective chip 214, both gold-plated at a top and a bottom, are supported by header 204 and are in an electrical contact therewith, the photodiode chip 212 resting on an island 205, which is a part of header 204. A wire 216 connects the other electrical contact of photodiode chip 212 to output terminal 208, and a wire 218 connects the other electrical contact of protective chip 214 to the same terminal 208. The role of the chip 214 is to provide ESD protection to photodiode chip 212. Protective chip 214 is mounted to header 204 and electrically wired to the output terminal 208 using the same methods and equipment as methods and equipment used to mount the photodiode chip 212. Because of this, no additional process development and equipment installation is required to mount protective chip 214 into the housing 202. Since protective chip 214 fits into the housing 202, outer dimensions and a pin-out of the photodiode assembly stay the same.

A Zener diode chip can be used as the protective chip 214. For example, for a photodiode with a typical reverse bias voltage of −5V and maximum allowable reverse voltage of −25V, a Zener or an avalanche diode with a clamping voltage of −15V can be used. In order to avoid an increase in the dark current and electrical capacity of the photodiode assembly 200, it is important to choose a Zener diode chip with low reverse current, for example less than 0.02 nA, and low electrical capacitance, for example, less than 8 pF.

Other ways of packaging a Zener diode are possible in the scope and spirit of present invention. For example, one can use a Zener diode chip with both contacts located at the top side of the chip, and connect these contacts to the output electrodes 206 and 208 of the housing 202, even though the one-wire connection shown in FIG. 2 is preferable.

Instead of mounting protective chip 214 into a photodiode housing 202, one can pre-mount a photodiode chip and a protecting chip onto a common substrate, which can subsequently be mounted into a photodiode housing according to a standard procedure.

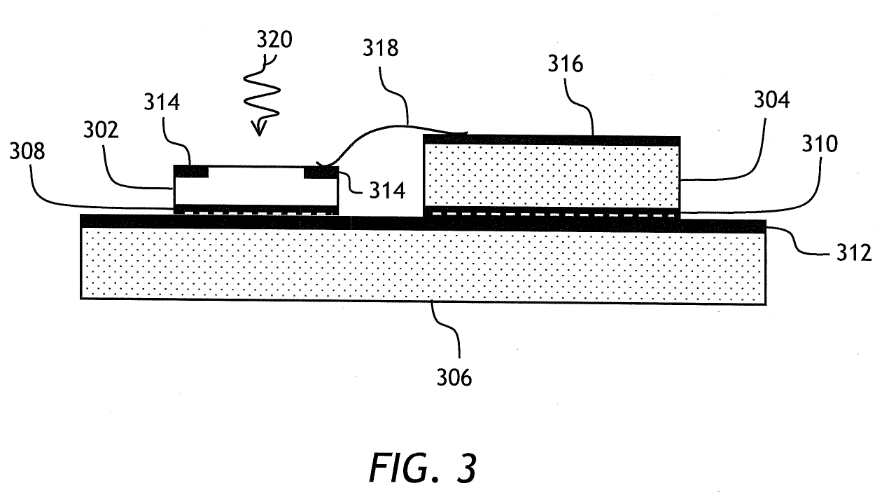

FIG. 3 shows a photodiode chip 302 and a Zener diode chip 304 mounted on a substrate 306. A bottom surface 308 of photodiode chip 302, and a bottom surface 310 of the Zener chip 304 are metalized. A top surface 312 of the substrate 306 is also metalized. The mounting is performed by using a flip-chip solder-bump method. Top contacts 314 of photodiode chip 302 and 316 of Zener diode chip 304 are connected using a wirebond 318. A photon 320 is detected by the photodiode 302, the photodiode 302 being protected from ESD by Zener diode chip 304.

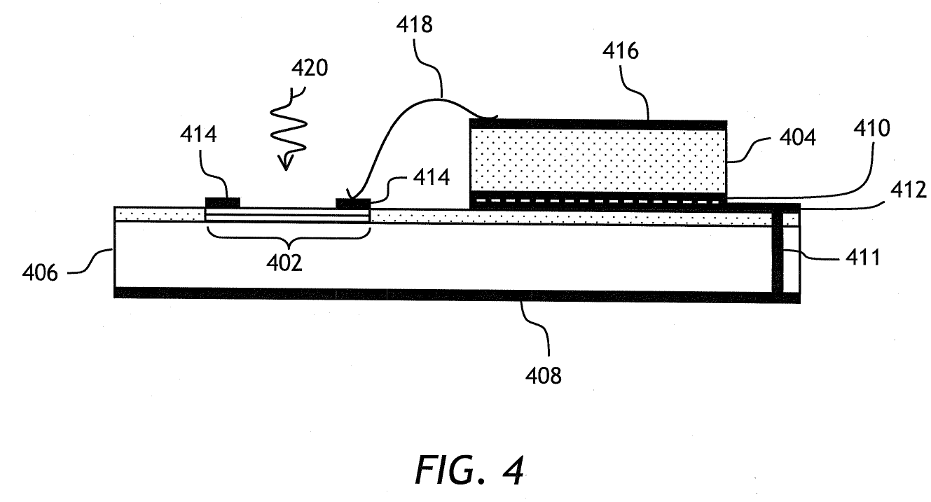

Turning now to FIG. 4, a cross-sectional view of another preferred embodiment of a photodiode with high ESD damage threshold is shown. A photodiode layer structure 402, fabricated on a substrate 406, has a bottom contact 408 and a top contact 414. The bottom contact 408 is electrically connected to a metalized layer 412, disposed on top of substrate 406. The electrical connection is formed by means of a via 411 going through substrate 406. A Zener diode chip 404, having a bottom contact 410 and a top contact 416, is mounted onto the metalized layer 412 by using a flip-chip solder-bump method. The top contacts 414 of photodiode structure 402 and 416 of Zener diode chip 404 are connected by a wirebond 418. A photon 420 is detected by the photodiode structure 402, said structure being protected from ESD by Zener diode chip 404.

The advantage of the photodiode of FIG. 4 is that no additional substrate is required to mount the chips together, since Zener diode chip 404 is mounted directly to substrate 406 on which photodiode layer structure 402 is fabricated. Another way of packaging the two chips together is to mount a photodiode chip onto a Zener diode chip.

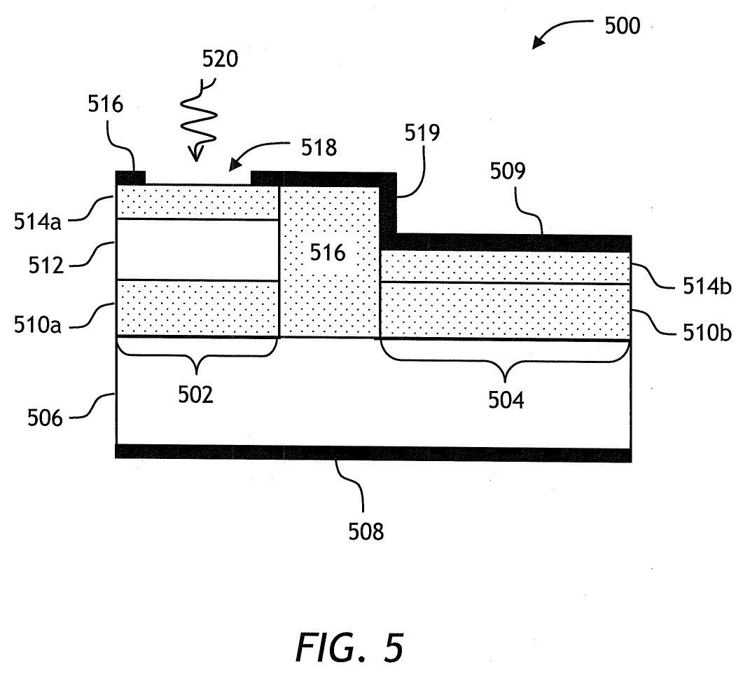

Turning now to FIG. 5, a cross-sectional view of yet another preferred embodiment of a photodiode with increased ESD damage threshold is shown. In the embodiment of FIG. 5, both a photodiode structure 502 and a protective diode structure 504 are fabricated on a common substrate 506. The photodiode structure 502 is an avalanche photodiode structure comprising a multiplication layer 510a, an absorption layer, or intrinsic layer 512, and a top junction layer 514a. The protective diode structure 504 is an avalanche diode structure comprising a multiplication layer 510b and a junction layer 514b. An electrical isolation region 516 is disposed in between the structures 502 and 506. The region 516 provides isolation of the avalanche photodiode structure 512 from avalanche diode structure 504. The resulting double diode structure 500 has a common bottom contact layer 508 and a common top contact layer 509. In the figure a photon 520 is shown detected in a window 518 of avalanche photodiode structure 502, wherein said structure is protected from ESD by avalanche diode structure 504.

The diode structures 502 and 504 are based on semiconductor homostructures or heterostructures. The layers 510a-510b, 512, and 514a-514b are manufactured by MOCVD epitaxial growth or by other methods established in the art, suitable for fabrication of avalanche diodes. The isolation region 516 can be implemented by a buried ion implantation or wet oxidation. The pairs of layers 510a and 510b, 514a and 514b can be grown together, or separately using masks of photoresist. Step 519 in top contact layer 509 may be avoided if thicknesses of layers in stacks 502 and 504 are properly adjusted to match the total thicknesses. The advantage of the double diode structure 500 is that it combines high detection sensitivity and high gain-bandwidth product of avalanche photodiode structure 502 with high ESD damage threshold provided by avalanche diode structure 504. Without the protective avalanche diode structure 504, avalanche photodiode structure 502 could be easily damaged by an ESD through the structure 502. A regular p-n or a p-i-n photodiode structure can be employed instead of structure 502, and a Zener diode structure can be employed instead of structure 504.

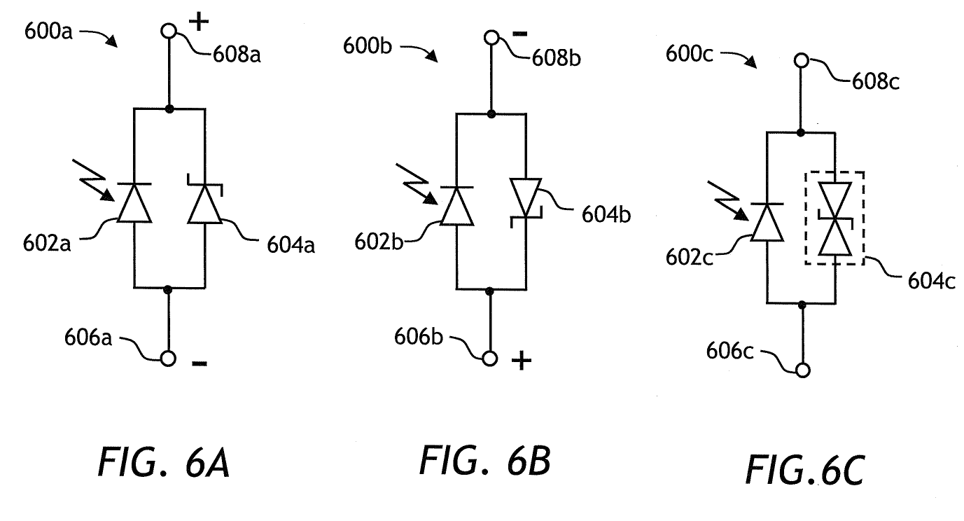

Turning now to FIGS. 6A, 6B, and 6C, various connection layouts of a photodiode and a protective diode are illustrated by means of electrical diagrams. A protected photodiode circuit 600a of FIG. 6A includes a photodiode 602a connected in parallel, cathode-to-cathode and anode-to-anode, to a Zener diode 604a. An arrow next to photodiode 602a is a part of a standard notation and symbolizes an impinging photon, not an ESD pulse. Circuit 600a is suitable for a photoconductive mode of a photodiode operation. A voltage applied to terminals 606a and 608a of FIG. 6A will reverse-bias both diodes 602a and 604a. When arriving ESD pulse has the same polarity as the biasing voltage, Zener diode 604a will conduct the ESD-generated current. When an arriving ESD pulse has the opposite polarity to the biasing voltage, both diodes 602a and 604a will conduct. Since a resistivity of a conducting diode is small, ESD through a conducting diode does not usually cause any damage.

More importantly, since both diodes are mounted into the same housing and, preferably, onto the same substrate, the electrical impedance of leads between the diodes is small. Consequently, since the surface area of a Zener diode is, in most cases, larger than the respective area of a photodiode, most ESD current will flow through a Zener diode thus protecting a photodiode from damage.

A protected photodiode circuit 600b of FIG. 6B includes a photodiode 602b connected in parallel, cathode-to-anode and anode-to-cathode, to a Zener diode 604b. Circuit 600b is suitable for a photovoltaic mode of a photodiode operation. A voltage, appearing at terminals 606b and 608b in response to illuminating photodiode 602b, will reverse-bias Zener diode 604b. Depending on the polarity of arriving ESD pulse, either Zener diode 604b, or photodiode 602b will conduct the ESD-generated current. Since a resistivity of a forward-biased diode is small, no damage is usually caused.

A preferable protected photodiode circuit 600c of FIG. 6C includes a photodiode 602c connected in parallel to a pair of Zener diodes 604c. Circuit 600c is suitable for a photovoltaic or a photoconductive mode of a photodiode operation. A voltage, appearing at terminals 606c and 608c upon illuminating photodiode 602c with light, in the photovoltaic mode, or a voltage used to reverse bias photodiode 602c, in the photoconductive mode of operation, will reverse bias one of Zener diodes in the pair of diodes 604c. When an ESD pulse arrives, both Zener diodes conduct and protect photodiode 602c, regardless of mode of operation.

Any connection configuration of FIGS. 6A-6C can be used in the ESD protected photodiodes of FIG. 2 through FIG. 5, except for cases involving p-i-n and avalanche photodiodes, which are employed in the photoconductive mode of operation. For these cases, connection configurations of FIG. 6A or 6C should be used.

The connection diagrams of FIGS. 6A-6C, however, share a common drawback. Since a photodiode and a protective diode are connected in parallel, an electrical capacity of the diode pair increases by the capacity of the protective diode used. A photodiode capacity has a direct bearing on its speed and, therefore, it is highly desirable to minimize the effect of capacity of a protective diode, which can have a large surface area and large associated electrical capacity due the requirement to withstand a peak current of an ESD pulse.

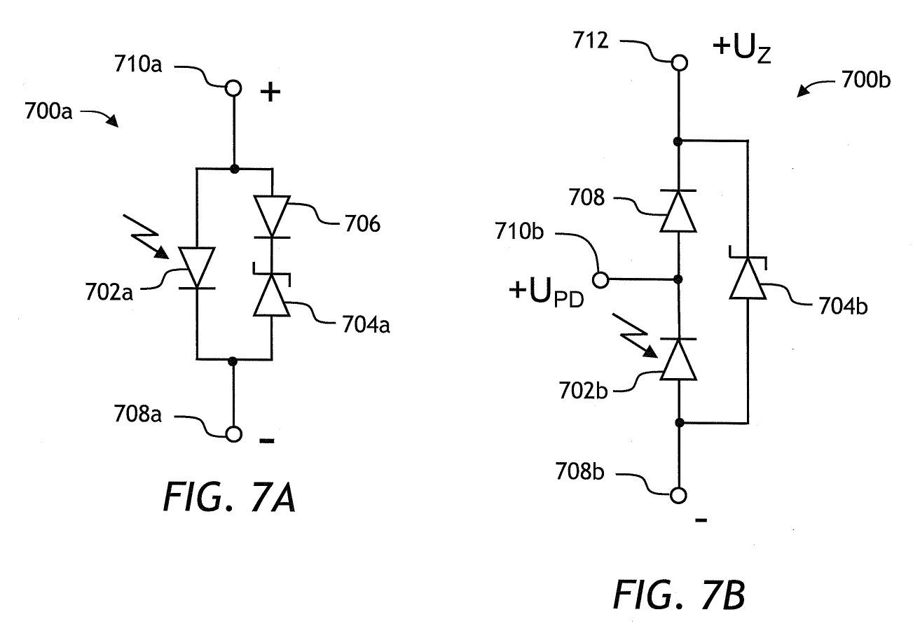

Referring now to FIGS. 7A and 7B, electrical diagrams illustrating preferred connection diagrams 700a and 700b of photodiodes 702a, 702b to a protective circuit consisting of Zener diodes 704a, 704b and regular p-n diodes 706 and 708, are shown. The regular p-n diodes 706 and 708 are used to minimize the capacity increase due to a protective circuit, as follows.

For a photovoltaic mode of operation, scheme 700a of FIG. 7A is preferable. The connection diagram 700a of FIG. 7A depicts Zener diode 704a connected in series, cathode-to-cathode, to p-n diode 706. The pair of diodes 704a and 706 is connected in parallel to photodiode 702a. As has been noted, photodiode 702a is used in the photovoltaic mode. In this mode, a small voltage appears in response to illumination of photodiode 702a with light. The polarity of the voltage is such that Zener diode 704a is reverse biased, and p-n diode 706 is forward biased. However, since the voltage is small, typically less than 1 Volt, the resistivity of diode 706 is still high. Since diode 706 is connected in series with Zener diode 704a, the capacity of the pair of diodes is largely determined by the smaller capacity of the two, which is usually the capacity of p-n diode 706. When an ESD pulse, positive at electrode 710a, arrives, Zener diode 704a conducts and protects photodiode 702a. The p-n diode 706 is not damaged, since the ESD current flows in forward direction of said diode. The ESD pulse of the opposite polarity is not a concern either, since the photodiode 702a itself will conduct in that instance.

For the photoconductive mode of operation, configuration 700b of FIG. 7B is preferable. Photodiode 702b is reverse biased by a voltage +U_{PD} applied between electrodes 708b and 710b, as shown. The Zener diode 704b is reverse biased by a voltage +U_{Z} applied to a terminal 712. The voltage +U_{Z} is higher than the voltage +U_{PD}. The reason for biasing Zener diode 704b to a higher voltage than photodiode 702b is that, upon increasing the voltage, the electric capacity of Zener diode 704b decreases. The function of diode 708, which is reverse biased, is twofold. First, diode 708 de-couples voltages +U_{PD} and +U_{Z} from each other, and second, it further reduces overall electrical capacity of a protected photodiode circuit according to configuration 700b, since photodiode 702b is connected to a pair of serially connected, reverse-biased diodes 708 and 704b.

Any connection scheme of FIGS. 7A and 7B can be used in the ESD protected photodiodes of FIG. 2 through FIG. 5, except for cases involving p-i-n or avalanche photodiodes, which are employed in the photoconductive mode. For these cases, connection configurations of FIG. 7B should be used.

What is claimed is:

1. A photodiode assembly comprising:
a substrate,
a photodiode structure having first and second electrical terminals and an electrostatic discharge protective diode structure having first and second electrical terminals, wherein both structures are supported by the substrate, and
wherein the first terminal of the photodiode structure is connected to the first terminal of the protective diode structure, and the second terminal of the photodiode structure is connected to the second terminal of the protective diode structure.

2. A photodiode assembly of claim 1, wherein the photodiode structure comprises a p-i-n photodiode or an avalanche photodiode.

3. A photodiode assembly of claim 1, wherein the protective diode structure comprises a Zener diode or an avalanche diode.

4. A photodiode assembly of claim 1 further comprising a housing having first and second electrodes, wherein:
the photodiode and the protective diode structures are disposed inside the housing;
the first terminal of the photodiode structure is electrically connected to the first electrode, and
the second terminal of the photodiode structure is electrically connected to the second electrode.

5. A photodiode assembly of claim 1, wherein:
the substrate has a conducting top surface,
the photodiode structure is selected from a group consisting of a p-n photodiode chip, a p-i-n photodiode chip, or an avalanche photodiode chip, and the first and the second terminals of the photodiode structure form a top and a bottom conducting layer of said photodiode chip;
the protective diode structure is a Zener or an avalanche diode chip, and the first and the second terminals of the protective diode structure form a top and a bottom conducting layer of the Zener or the avalanche diode chip; and,
the bottom conducting layer of the photodiode chip, and the bottom conducting layer of the Zener or the avalanche diode chip contact the conducting top surface of the substrate.

6. A photodiode assembly of claim 5 further comprising a housing having first and second electrodes, wherein:
the photodiode chip and the Zener or the avalanche diode chip are disposed inside the housing;
the substrate is a header of the housing, and the conducting top surface of the header is electrically connected to the second electrode;
the bottom conducting layer of the photodiode chip is in electrical contact with the conducting top surface of the header;
the bottom conducting layer of the Zener or the avalanche diode chip is in electrical contact with the conducting top surface of the header;
the top conducting layers of the photodiode and the Zener or the avalanche diode chips are in electrical contact with the first electrode of the housing.

7. A photodiode assembly of claim 6, wherein the top and the bottom conducting layers of the photodiode and, or the Zener or the avalanche diode chips are Au or Ag plated layers.

8. A photodiode assembly of claim 1, wherein:
the photodiode structure is a p-i-n or an avalanche photodiode layer structure, and
the substrate is a substrate of the p-i-n or the avalanche photodiode layer structure.

9. A photodiode assembly of claim 1, wherein:
the protective diode structure is a Zener or an avalanche diode layer structure, and
the substrate is a substrate of the Zener or the avalanche diode layer structure.

10. A photodiode assembly of claim 1, wherein:
the substrate is a semiconductor substrate;
the photodiode structure is a p-i-n or an avalanche photodiode layer structure formed on the semiconductor substrate;
the protective diode structure is a Zener or an avalanche diode layer structure formed on the semiconductor substrate.

11. A photodiode assembly of claim 10, further comprising an electrical isolation region disposed on the substrate between the photodiode and the protective diode layer structures.

12. A photodiode assembly of claim 1, wherein photodiode and the protective diode structures are connected cathode-to-cathode.

13. A photodiode assembly of claim 1, wherein the photodiode and the protective diode structures are connected cathode-to-anode.

14. A photodiode assembly of claim 1, wherein a clamping voltage of the protective diode structure is greater than a working voltage of the photodiode structure, but smaller than a breakdown voltage of the photodiode structure.

15. A photodiode assembly of claim 1, wherein a clamping voltage of the protective diode structure is between 5 and 25 Volts.

16. A photodiode assembly of claim 1, wherein an electrical capacity of the protective diode structure is smaller than 8 pF.

17. A photodiode assembly of claim 1, wherein in operation, a dark current through the protective diode structure is smaller than a dark current through the photodiode structure.

18. A photodiode assembly of claim 1, wherein in operation, a dark current through the protective diode structure is smaller than 0.02 nA at 5V applied to the protective diode structure in a reverse-bias direction.

19. A photodiode assembly comprising a photodiode having a cathode and an anode, and an electrostatic discharge protective circuit having first and second electric terminals, wherein the photodiode and the electrostatic discharge protective circuit are connected in parallel, and the electrostatic discharge protective circuit comprises a protective diode having a cathode and an anode.

20. A photodiode assembly of claim 19, wherein the protective diode is a Zener diode or an avalanche diode.

21. A photodiode assembly of claim 19, wherein the photodiode and a protective diode have their cathodes connected together, and have their anodes connected together.

22. A photodiode assembly of claim 19, wherein the cathode of the photodiode is connected to the anode of the protective diode, and vice versa.

23. A photodiode assembly of claim 19, wherein the electrostatic discharge protective circuit further comprises a secondary diode connected in series with the protective diode.

24. A photodiode assembly of claim 23, wherein the secondary diode is selected from a group consisting of a Zener, an avalanche, or a regular p-n semiconductor diode.

25. A photodiode assembly of claim 23, wherein the diodes comprising the electrostatic discharge protective circuit are connected cathode-to-cathode or anode-to-anode.
